(19) United States
(12) Patent Application Publication
(10) Pub. No.: US 2018/0332699 A1
(43) Pub. Date: Nov. 15, 2018

(54) PRINTED CIRCUIT BOARD

(71) Applicant: UNLIMITER MFA CO., LTD., EDEN ISLAND (SC)

(72) Inventors: KUO-PING YANG, TAIPEI (TW); NEO BOB CHIH YUNG YANG, TAIPEI (TW); LIN-HE CHU, TAIPEI (TW); WEN-CHIANG WU, TAIPEI (TW); SHIH-KANG HUANG, TAIPEI (TW); YI-YEN CHIANG, TAIPEI (TW)

(73) Assignee: UNLIMITER MFA CO., LTD., EDEN ISLAND (SC)

(21) Appl. No.: 16/037,464

(22) Filed: Jul. 17, 2018

Related U.S. Application Data
(63) Continuation-in-part of application No. 15/437,470, filed on Feb. 21, 2017, now abandoned.

(51) Int. Cl. H05K 1/02; H05K 1/09; H05K 1/11

(52) U.S. Cl. CPC H05K 1/0206; H05K 1/09; H05K 2201/062; H05K 2201/10636; H05K 2201/09427; H05K 1/113

(57) ABSTRACT

A printed circuit board has a copper clad laminate and a plurality of holes. The copper clad laminate for dissipating heats generated from a chip when the chip operates has a plurality of solder paste disposed areas. The plurality of holes situate on the copper clad laminate and each of the holes does not communicate with others, wherein the plurality of holes are nonconductors. Each of the solder paste disposed areas is surrounded by the plurality of holes and each solder paste disposed areas is surrounded by at least two holes.

### BACKGROUND OF THE INVENTION

### 1. Field of the Invention

The present invention relates to a printed circuit board (PCB), particularly to a printed circuit board having a copper clad laminate with a plurality of grooves for improving the contact yield of solder paste for Bottom Termination Components.

### 2. Description of the Related Art

With the rapid development of electronic devices and consumer demand for electronic products to be high performance and compact and slim, the requirement for dissipating heats from a chip within an electronic device is also growing. Surface Mount Technology (SMT) is a method of soldering an electronic chip to a printed circuit board. Hereafter, a QFN (Quad Flat No-leads) chip is used as an example. To achieve good thermal efficiency, sufficient amount of solder paste and ensuring solder joint reliability are key issues for QFN chips. However, due to the excellent heat dissipating ability of copper, the soldering temperature drops rapidly during the course of the surface mount technology procedure, which causes the QFN chip to float and cold soldering of the perimeter I/O (Input/Output) of the QFN chip. As a result, the contact area between the thermal pad area of the QFN chip and the printed circuit board is less than 50%, and the reliability of the QFN chip is consequently decreased. Accordingly, there is a need for improvement.

Further, although prior art US2002/0050380 discloses solder-applied areas are surrounded by through holes, the disadvantage of US2002/0050380 is that applying solder resist and through holes would reduce the contact area between the thermal pad of the QFN chip and solder resist would generate void during the course of SMT procedure; i.e. US2002/0050380 cannot provide sufficient amount of solder paste and ensuring solder joint reliability for QFN chips. Thus, an improvement is required.

### SUMMARY OF THE INVENTION

It is a major objective of the present invention to provide a printed circuit board having a copper clad laminate with a plurality of holes by which the contact yield of solder paste in the printed circuit board can be improved.

To achieve the above objective, the printed circuit board of the present invention includes a copper clad laminate and a plurality of holes. The copper clad laminate is used for dissipating heats generated from a chip. The copper clad laminate includes a plurality of solder paste disposed areas. The plurality of holes situate on the copper clad laminate. Each of the holes does not communicate with others, wherein the plurality of holes are nonconductors. Each of the solder paste disposed areas is surrounded by the plurality of holes and each of the solder paste disposed areas is surrounded by at least two holes.

### BRIEF DESCRIPTION OF THE DRAWINGS

FIG. 1 is a schematic diagram of a printed circuit board according to an embodiment of the present invention;

FIGS. 2A to 2D show different representations of solder paste disposed areas surrounded by holes;

FIGS. 3A and 3B are cross sectional views before and after the printed circuit board of the present invention being mounted to a QFN chip;

FIG. 4 is a schematic diagram of a printed circuit board according to another embodiment of the present invention;

FIG. 5 is a cross-sectional view of a printed circuit board according to another embodiment of the present invention; and

FIG. 6 is a cross-sectional view of a printed circuit board according to another embodiment of the present invention with a QFN chip mounted on it.

### DETAILED DESCRIPTION OF THE PREFERRED EMBODIMENT

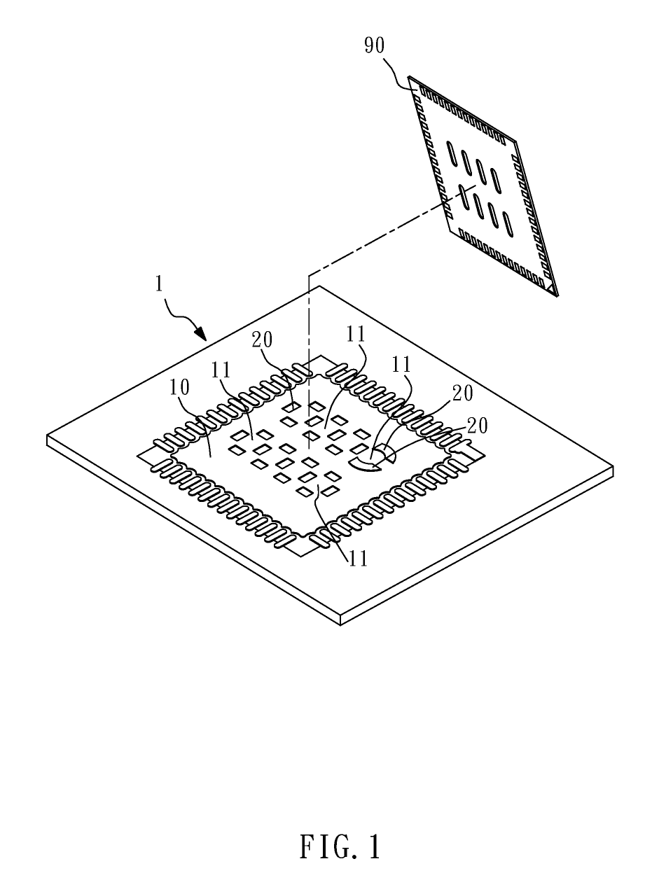

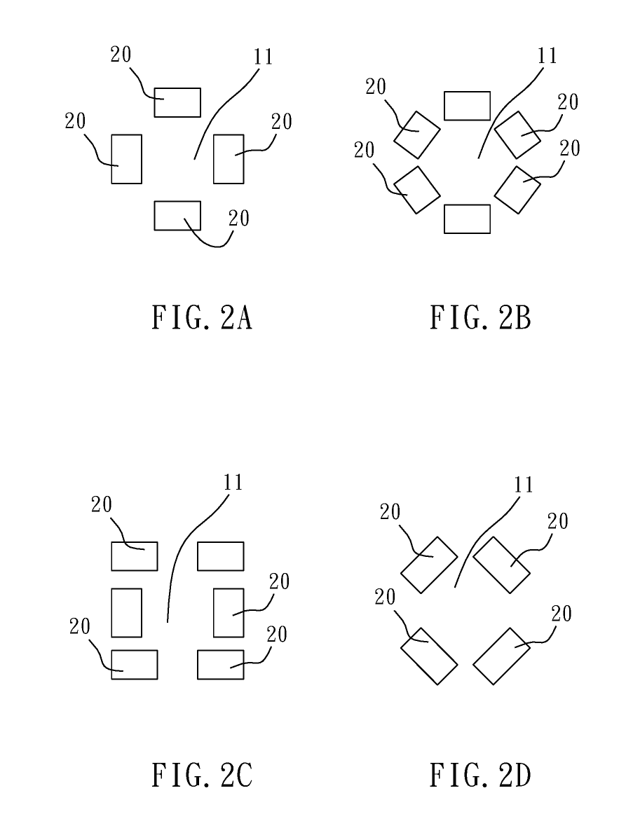

Hereafter, the technical content of the present invention will be better understood with reference to preferred embodiments. Please refer to FIG. 1 which is a schematic diagram of a printed circuit board in an embodiment of the present invention and FIGS. 2A to 2D which show different representations regarding solder paste disposed areas surrounded by a plurality of holes.

As shown in FIG. 1, the printed circuit board 1 of the present invention includes a copper clad laminate 10 and a plurality of grooves 20, wherein the plurality of grooves 20 situate on the copper clad laminate 10, such that the copper clad laminate 10 can be mounted to a chip 90 through a Surface Mount Technology. In the present embodiment, the copper clad laminate 10 is a thermal plate of a QFN (Quad Flat No-leads) chip. The chip 90 is a QFN chip, but the present invention is not limited thereto. The chip 90 can also be other types of Bottom Termination Components. The grooves 20 are nonconductors, wherein each of the grooves 20 does not communicate with others.

As shown in FIG. 1, in the present embodiment, the copper clad laminate 10 includes a plurality of solder paste disposed areas 11. The plurality of grooves 20 are dispersedly arranged around the plurality of solder paste disposed areas 11. The plurality of solder paste disposed areas 11 are solder joints of thermal pads for the QFN (Quad Flat No-leads) chip. In the present embodiment, each of the solder paste disposed areas 11 are surrounded by at least two grooves 20a. As shown in FIG. 1, each of the solder paste disposed areas 11 from a top view looks like a rectangle, and the grooves 20 are dispersed in each side of the rectangle. Each of the grooves 20 has a gap therebetween, such that the solder paste disposed areas 11 are in communication with the copper clad laminate 10 through the gap, but the present invention is not limited thereto. Actually, as shown in FIG. 2A to FIG. 2D, the solder paste disposed areas 11 from a top view may look like any geometric shape, such as round, triangle, or polygonal shape. The plurality of grooves 20 are dispersed around the plurality of sides in the geometric shape, and each of the grooves 20 are not in communication with each other, such that the solder paste disposed areas 11 can be in communication with the copper clad laminate 10 through the gap. It should be noted here that the number of the solder paste disposed areas 11 in the present embodiment is 8, and the solder paste disposed areas 11 are arranged in parallel in four rows on the copper clad laminate 10, but the present invention is not limited thereto. The number and arrangement of the solder paste disposed areas 11 vary depending on the design of the chip 90. In addition, the shape of the grooves 20 is not particularly limited. The grooves 20 may be of other geometries, such as an arc shown as the grooves 20a in FIG. 1.

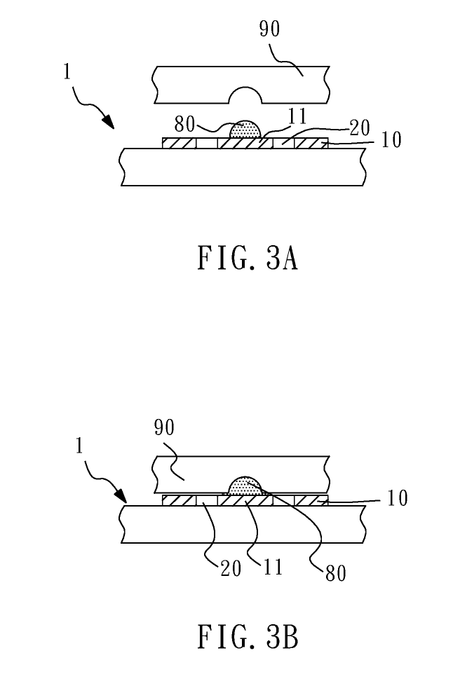

Hereafter, please still refer to FIG. 1. Also refer to FIGS. 3A and 3B which are cross sectional views before and after the printed circuit board being mounted to a chip.

As shown in FIGS. 3A and 3B, when the surface mount technology is processed, the solder paste 80 situates on the solder paste disposed areas 11. Through the design that the grooves 20 situate on the copper clad laminate 10, the solder paste 80 is limited onto the solder paste disposed areas 11. The solder paste 80 will not collapse when heated, which increases the contact yield between the chip 90 and the copper clad laminate 10 when the solder paste 80 is in contact with the chip 90. According to an embodiment of the present invention, when the surface mount technology is implemented, a fixture having a plurality of circular openings may be placed on the copper clad laminate 10, where the circular openings correspond to the respective solder paste disposed areas 11, to facilitate the placement of the solder paste 80 in the solder paste disposed areas 11. The solder paste 80 is kept in a spherical shape as shown in FIGS. 3A and 3B so that the solder paste 80 does not collapse when heated, and thus the contact yield between the chip 90 and the copper clad laminate 10 can be improved.

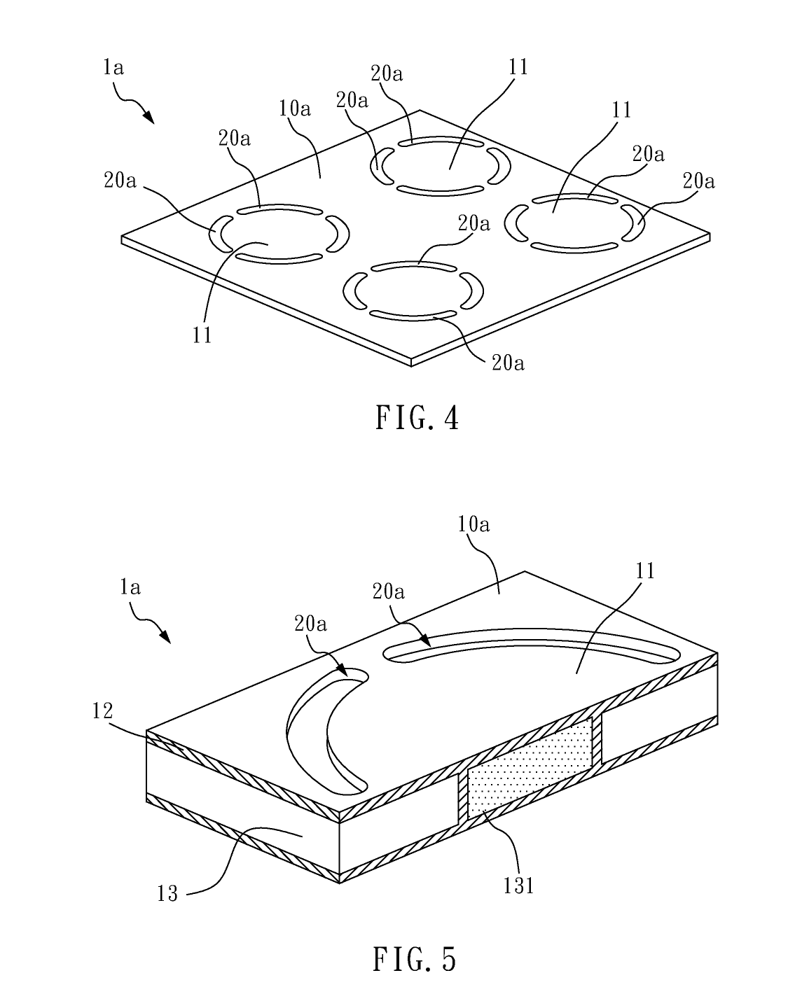

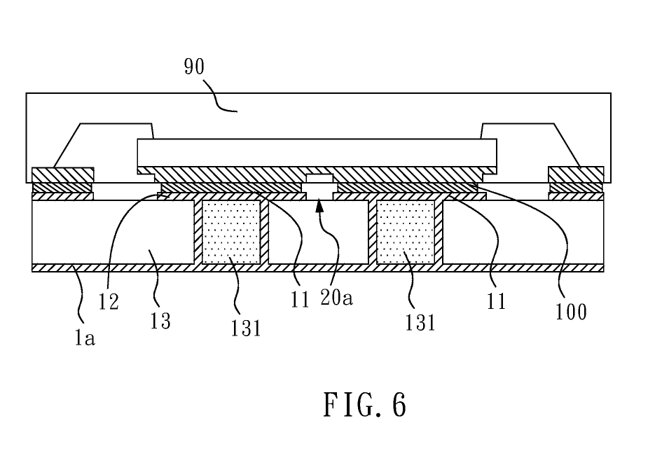

Please refer to FIG. 4, which is a schematic diagram of a printed circuit board in another embodiment of the present invention, and FIGS. 5 to 6, which present cross-sectional views of a printed circuit board according to another embodiment of the present invention and a cross sectional view of the printed circuit board according to another embodiment of the present invention with a QIN chip mounted on it.

As shown in FIG. 4, FIG. 5 and FIG. 6, in the present embodiment, the printed circuit board 1a of the present invention includes a copper clad laminate 10a and a plurality of grooves 20a. The copper clad laminate 10a. includes a plurality of solder paste disposed areas 11, a copper layer 12 and a laminate layer 13. The laminate layer 13 is situated beneath the copper layer 12 and has at least one via hole 131. As shown in FIG. 5 and FIG. 6, the at least one via hole 131 is covered with copper and fulfilled with resin or copper such that the horizontal level of the opening of the at least one via hole 131 is equal to the top surface of the copper layer 12. The reason for ensuring that the horizontal level of the opening of the at least one via hole 131 is equal to the top surface of the copper layer 12 is to increase the contact area between the copper layer 12 and the QFN chip 90 to overcome the defects of the prior art related to reliability issues caused by the inadequate contact area between the copper layer 12 and the QFN chip 90.

As shown in FIG. 4 and FIG. 5, the plurality of grooves 20 are situate on the copper layer 12 and each of the solder paste disposed areas 11 are surrounded by at least two of the grooves 20a. The grooves 20a are employed for allowing gas yielded during the SMT (surface mount technology) procedure to escape via the grooves 20a and thus prevent the formation of voids. Further, the grooves 20a also are applied for increasing soldering temperature to ensure solder joint reliability and as shown in FIG. 5, a depth of the groove 20a equals to or is less than the height of the copper layer 12. For example, according to an embodiment of the present invention, when the copper layer 12 comprises 0.5 OZ copper metal, the height of the copper clad laminate 10a and the depth of each of the grooves 20a will be approximately larger than 1.4 mil and less than 2 mil. In addition, each of the grooves 20a does not communicate with any other and is separated by a gap. The gaps are employed for thermal relief and then heat is not trapped between the QFN chip 90 and the printed circuit board 1. As shown in FIG. 5 and FIG. 6, in the present embodiment, the height of the grooves 20a is equal to the height of the copper layer 12, and solder paste 100 is situated on the solder paste disposed area 11. It is noted that the grooves 20a can be circular, triangular, rectangular, or polygonal in shape.

The design of the grooves 20, 20a not only maintains a sufficient temperature during the course of the SMT procedure to prevent insufficient soldering but also maintains an adequate contact area for the copper layer 12 and the QFN chip 90 to protect the QFN chip 90 from overheating while the QFN chip 90 operates. Moreover, through the design that the grooves 20, 20a situate on the copper clad laminate 10, 10a in the present invention, the position of the solder paste 80 is limited to the solder paste disposed areas 11, such that in the process of the surface mount technology to the printed circuit board 1, 1a, the amount of sufficient solder of the chip 90 is increased, and the contact yield between the chip 90 and the copper clad laminate 10, 10a is improved.

It should be noted that the described embodiments are only for illustrative and exemplary, and that various changes and modifications may be made to the described embodiments without departing from the scope of the invention as disposed by the appended claims.

What is claimed is:

1. A printed circuit board, for mounting of a Bottom Termination Component, the printed circuit board comprising:
a copper clad laminate, used for dissipating heat generated by a chip, the copper clad laminate comprising a plurality of solder paste disposed areas, a copper layer and a laminate layer, wherein the laminate layer is situated beneath the copper layer and the laminate layer has at least one via hole; and
a plurality of grooves, situated on the copper layer; each of the solder paste disposed areas is surrounded by at least two of the grooves, wherein each of the grooves does not communicate with any other and the grooves are separated by gaps.

2. The printed circuit board as claimed in claim 1, wherein a height of the plurality of grooves is equal to the height of the copper layer.

3. The printed circuit board as claimed in claim 2, wherein the grooves are circular, triangular, rectangular, or polygonal in shape.

4. The printed circuit board as claimed in claim 1, wherein the at least one via hole is covered with copper and filled with resin or copper.

5. The printed circuit board as claimed in claim 1, wherein the gaps are employed for thermal relief.

6. The printed circuit board as claimed in claim 1, wherein a height of the plurality of grooves is less the height of the copper layer.

7. The printed circuit board as claimed in claim 1, wherein the Bottom Termination Component is a QFN (Quad Flat No leads) chip.
